(19) United States
(12) Patent Application Publication
(10) Pub. No.: US 2014/0246073 A1
(43) Pub. Date: Sep. 4, 2014

(54) SOLAR CELL AND SOLAR CELL MODULE USING THE SAME

(71) Applicant: LG INNOTEK CO., LTD., Seoul (KR)

(72) Inventor: Gi Gon Park, Seoul (KR)

(73) Assignee: LG INNOTEK CO., LTD., Seoul (KR)

(21) Appl. No.: 14/349,944

(22) PCT Filed: Oct. 4, 2012
(86) PCT No.: PCT/KR2012/008034

§ 371 Date: Apr. 4, 2014

(30) Foreign Application Priority Data
Oct. 5, 2011 (KR) 10-2011-0101105

(51) Int. Cl. H01L 31/0224; H01L 31/042

(52) U.S. Cl. CPC H01L 31/022408; H01L 31/042
USPC 136/244; 136/256

(57) ABSTRACT

Disclosed are a solar cell and a solar cell module using the same. The solar cell includes a back electrode on a support substrate; a light absorbing part on a top surface and one side of the back electrode; and a front electrode on a top surface and one side of the light absorbing part and directly making contact with a top surface of the support substrate.

### TECHNICAL FIELD

The embodiment relates to a solar cell and a solar cell module using the same.

### BACKGROUND ART

Recently, the requirement for new renewable energy and the interest of the new renewable energy have been more increased due to the serious environmental pollution and the lack of fossil fuel. In this regard, a solar cell is spotlighted as a pollution-free energy source for solving the future energy problem because it rarely causes environmental pollution and has the semi-permanent life span and there exists infinite resources for the solar cell.

Solar cells may be defined as devices to convert light energy into electric energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

The minimum unit of the solar cell is a cell. In general, one cell generates a very small voltage of about 0.5V to about 0.6V. Therefore, a solar cell module manufactured in a panel structure by connecting a plurality of cells to each other in series on a substrate to generate voltages in a range of several voltages to several hundreds of voltages is used.

In recent years, research on a Building Integrated Photovoltaic (BIPV) integrating a solar cell module with a building has been actively performed. Because a BIPV module may minimize electric energy consumption of the building by using power generated from a solar cell, a building adopting the BIPV module has been gradually increased in view of saving energy.

However, when the BIPV module according to the related art is applied to a lighting facility of a building, solar light may not be readily transmitted to an interior of the building due to a structural problem and an amount of light transmitted to the interior of the building may not be adjusted.

### DISCLOSURE OF INVENTION

### Technical Problem

The embodiment provides a BIPV module which can easily control an amount of light transmitted to an interior of a building according to selection of a user.

### Solution to Problem

According to the embodiment, there is provided a solar cell including a back electrode on a support substrate; a light absorbing part on a top surface and one side of the back electrode; and a front electrode on a top surface and one side of the light absorbing part and directly making contact with a top surface of the support substrate.

According to the embodiment, there is provided a solar cell module including a first solar cell including a first back electrode on a support substrate, a first light absorbing part on a top surface and one side of the first back electrode, and a first front electrode on a top surface and one side of the first light absorbing part; and a second solar cell including a second back electrode on the support substrate, a second light absorbing part on a top surface and one side of the second back electrode, and a second front electrode on a top surface and one side of the second light absorbing part.

According to the embodiment, there is provided a method of fabricating a solar cell module, including: forming a back electrode layer on a support substrate; forming a light absorbing layer on the back electrode layer; and forming a front electrode layer on the light absorbing layer.

### Advantageous Effects of Invention

In the solar cell according to the embodiment, the light absorbing part and the front electrode are provided on one side of the back electrode as well as the top surface of the back electrode. Accordingly, an interval between back electrodes may be widened in the solar cell.

Therefore, the solar cell module according to the embodiment can easily control transmittance of the solar cell module by adjusting an amount of light transmitted to an interior of a building according to the coating area of the back electrode layer.

### BRIEF DESCRIPTION OF DRAWINGS

FIG. 1 is a sectional view illustrating a section of a solar cell according to the related art;

FIG. 2 is a sectional view illustrating a section of a solar cell according to the embodiment; and

FIGS. 3 to 5 are sectional views showing a method of fabricating the solar cell module according to the embodiment.

### MODE FOR THE INVENTION

In the description of the embodiments, it will be understood that when a substrate, a layer, a film or an electrode is referred to as being “on” or “under” another substrate, another layer, another film or another electrode, it can be “directly” or “indirectly” on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

In the description of the embodiments, the term “transmittance” refers to an amount of solar light incident from the outside to an interior of a building through a solar cell module.

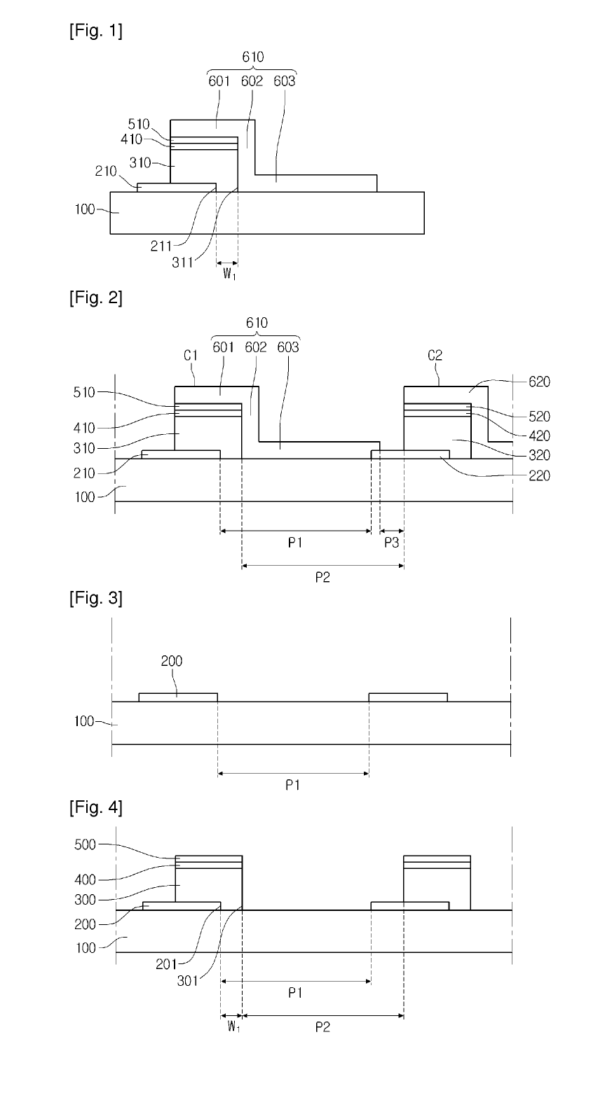

FIG. 1 is a sectional view illustrating a section of a solar cell according to the embodiment. Referring to FIG. 1, the solar cell according to the embodiment includes a support substrate 100, a back electrode 210, a light absorbing part 310, a buffer part 410, a high resistance buffer part 510, and a front electrode 610.

The support substrate 100 supports the back electrode 210, the light absorbing part 310, the buffer part 410, the high resistance buffer part 510, and the front electrode 610.

The support substrate 100 has high strength. The support substrate 100 may be transparent and may be rigid or flexible. For example, the support substrate 100 may include a glass substrate, a ceramic substrate such as alumina, a stainless steel substrate, a titanium substrate, or a polymer substrate.

The back electrode 210 is provided on the support substrate 100. The back electrode 210 is a conductive layer. The back electrode 210 may include one selected from the group consisting molybdenum (Mo), gold (Au), aluminum (Al), chrome (Cr), tungsten (W), and copper (Cu). Among them, since molybdenum (Mo) represents a thermal expansion coefficient less than that of the support substrate 100, the molybdenum (Mo) can prevent delamination due to a superior adhesion property, and can wholly satisfy the required characteristics.

The light absorbing layer 310 is provided on the back electrode 210. The light absorbing layer 300 may include group I-III-VI compounds. For example, the light absorbing part 310 may have a copper-indium-gallium-selenide(Cu(In,Ga)(Se,S)₂; CIGSS)-based crystal structure, a copper-indium-selenide-based crystal structure, or a copper-gallium-selenide-based crystal structure. The energy bandgap of the light absorbing part 310 may be in the range of about 1 eV to about 1.8 eV.

In more detail, the light absorbing part 310 is provided on a top surface and one side of the back electrode 210. For example, the light absorbing part 310 may cover the top surface and the one side of the back electrode 210. Referring to FIG. 1, the light absorbing part 310 provided on the one side of the back electrode 210 may directly make contact with a top surface of the support substrate 100.

In the solar cell according to the embodiment, the light absorbing part 310 may be formed in the one side of the back electrode 210 to prevent the back electrode 210 from being electrically connected to the front electrode 610.

In more detail, referring to FIG. 1, one side 311 of the light absorbing part 310 and one side 211 of the back electrode 210 are provided corresponding to each other. In this case, the one side 311 of the light absorbing part 310 is spaced apart from the one side 211 of the back electrode 210 by a predetermined interval W1.

The predetermined interval W1 between the one side 211 of the back electrode 210 and the one side 311 of the light absorbing part 310 may be equal to or greater than about 5 μm. In detail, the interval W1 between the one side of the back electrode 210 and the one side of the light absorbing part 310 may be in the range of about 5 μm to about 20 μm. However, the embodiment is not limited thereto. If the interval W1 between the one side 211 of the back electrode 210 and the one side 311 of the light absorbing part 310 is less than about 5 μm, the back electrode 210 may be connected to the front electrode 610. If the interval W1 between the one side 211 of the back electrode 210 and the one side of the light absorbing part 310 is greater than about 20 μm, a contact area of the light absorbing part 310 provided on the support substrate 100 becomes wide so that transmittance of the solar cell module may be deteriorated.

Meanwhile, the light absorbing part 310 is provided only in a part of the back electrode 210. That is, the light absorbing part 310 may expose a part of the back electrode 210. In detail, referring to FIG. 1, the light absorbing part 310 exposes a part of the top surface of the back electrode 210 and an opposite side of the back electrode 210. The exposed back electrode 210 is electrically connected to an adjacent front electrode of the solar cell, which will be described later in detail when explaining a solar cell module.

The buffer part 410 and a high resistance buffer part 420 may be additionally provided on the light absorbing part 310.

The buffer part 410 is provided on the light absorbing part 310. The buffer layer 410 includes cadmium sulfide (CdS), ZnS, InXSY, and InₓSe_{y}Zn(O, OH). The thickness of the buffer part 410 may be in the range of about 50 nm to about 150 nm, and the energy bandgap of the buffer layer part may be in the range of about 2.2 eV to about 2.4 eV.

The high resistance buffer layer 510 is provided on the buffer part 410. The high resistance buffer layer 510 includes i-ZnO which is not doped with impurities. The high-resistance buffer layer 510 may have the energy bandgap in the range of about 3.1 eV to about 3.3 eV. The high-resistance buffer part 510 can be omitted. As shown in FIG. 1, respective one ends of the light absorbing part 310, the buffer part 410, and the high resistance buffer part 510 may have the same cut surface.

The front electrode 610 may be provided on the light absorbing layer 310. For example, the front electrode 610 may directly make contact with the high-resistance buffer part 510 formed on the light absorbing layer 310.

The front electrode 610 may include a transparent conductive material. The front electrode 610 may have the characteristics of an n type semiconductor. In this case, the front electrode 610 forms an n type semiconductor together with the buffer part 410 to make a pn junction together with the light absorbing part 300 serving as a p type semi-conductor layer. For instance, the front electrode 610 may include aluminum-doped zinc oxide (AZO) or boron-doped zinc oxide (BZO). The front electrode 610 may have a thickness in the range of about 300 nm to about 1.5 um.

In detail, the front electrode 610 is provided on the top surface of the light absorbing part 310 and the one side of the light absorbing part 310. That is, the front electrode 610 may cover the top surface and the one side of the back electrode 310. Simultaneously, the front electrode 610 may directly make contact with the top surface of the support substrate 100. The front electrode 610 may include a transparent material. Even if the front electrode 610 is formed on the top surface of the support substrate 100, the front electrode 610 does not exert an influence upon the transmittance of the solar cell.

In detail, the front electrode 610 may include a first front electrode part 601 provided on a top surface of the light absorbing part 310, a second front electrode part 602 connected to an end of the first front electrode part 601 and provided in the one side of the light absorbing part 310, and a third front electrode part 603 connected to an end of the second front electrode part 602 and horizontally extending with respect to the support substrate 100. Meanwhile, although FIG. 1 illustrates the first front electrode part 601 to the third front electrode part 603 separately, this is illustrative purpose only and the embodiment is not limited thereto. That is, the first electrode part 601 to the third electrode part 603 may be integrally provided.

The third front electrode part 603 may function as a connection electrode which is electrically connected to an adjacent solar cell. In this case, the third front electrode part 603 may directly make contact with the top surface of the support substrate 100. As described above, since the front electrode part 603 includes a transparent conductive material, the front electrode formed on the top surface of the support substrate 100 may not exert influence upon the transmittance of the solar cell.

FIG. 2 is a sectional view illustrating a section of a solar cell according to the embodiment. The foregoing description of the solar cell may be basically incorporated with the description of this solar cell module. The solar cell module according to the embodiment may be Building Integrated Photovoltaic (BIPV).

Referring to FIG. 2, the solar cell module according to the embodiment includes a first solar cell C1 and a second solar cell C2. Although only two solar cells C1 and C2 are shown in FIG. 2, the embodiment is not limited thereto. That is, the solar cell module according to the embodiment may include at least two solar cells.

The first solar cell C1 includes a first back electrode 210 provided on the support substrate 100, a first light absorbing part 310 provided on a top surface and one side of the first back electrode 210, and a first front electrode layer 610 provided on a top surface and one side of the first light absorbing part 310. In detail, as shown in FIG. 2, the first solar cell C1 may further include a first buffer part 410 and a high resistance buffer part 510.

The second solar cell C2 includes a second back electrode 220 provided on the support substrate 100, a second light absorbing part 320 provided on a top surface and one side of the second back electrode 220, and a second front electrode layer 620 provided on a top surface and one side of the second light absorbing part 320. In detail, as shown in FIG. 2, the second solar cell C2 may further include a second buffer part 420 and a second high resistance buffer part 520. Referring to FIG. 2, the first front electrode 610 of the first solar cell C1 and the second front electrode 620 of the second solar cell C2 may directly make contact with the top surface of the support substrate 100, respectively. As described above, since the first front electrode part 610 and the second front electrode 620 include a transparent conductive material, they are formed even on the top surface of the support substrate 100 not to influence the transmittance of the solar cell.

Referring to FIG. 2, the first back electrode 210 and the second back electrode 220 are spaced apart from each other through a first pattern P1. The first back electrode 610 and the second front electrode 620 are spaced apart from each other through a third pattern P3.

The solar cell module according to the embodiment may easily control an amount of light transmitting the interior of a building by adjusting an interval of the first pattern P1. Accordingly, the solar cell module according to the embodiment may easily control transmittance. For example, the width of the first pattern P1 is in the range of about 3 mm to about 7 mm. Preferably, the width of the first pattern P1 is in the range of about 4 mm to about 5 mm. However, the embodiment is not limited to the above. In the description of the embodiments, the term “transmittance” refers to an amount of solar light incident from the outside to an interior of a building through a solar cell module.

If the interval of the first pattern P1 is wide, an amount of light transmitted to the interior of a building through the solar cell module may be increased. Accordingly, the transmittance of the solar cell module according to the embodiment may be improved. Accordingly, the solar cell module may be used as a BIPV module for lighting.

If the width of the first pattern P1 is narrow, the amount of light transmitted to the interior of a building through the solar cell module may be reduced. Accordingly, the transmittance of the solar cell module according to the embodiment may be deteriorated. Accordingly, the solar cell module may be used as a blind BIPV module.

The second solar C2 is electrically connected to the first solar cell C1. For instance, the second solar cell C2 may be serially connected to the first solar cell C1.

In detail, the second solar C2 may be electrically connected to the first solar cell C1 through the first front electrode 610 of the first solar cell C1 and the second back electrode 220 of the second solar cell C2. That is, the first front electrode 610 and the second back electrode 220 may function as a connection electrode, respectively.

For example, referring to FIG. 2, the first front electrode 610 may directly make contact with an opposite side of the second back electrode 220 and the top surface of the second back electrode 220. Accordingly, the second solar cell C2 may be electrically connected to the second solar cell C2.

In detail, the first front electrode 610 may include a first front electrode part 601 provided on a top surface of the first light absorbing part 310, a second front electrode part 602 connected to an end of the first front electrode part 601 and provided on one side of the first front electrode part 601, and a third front electrode part 603 connected to an end of the second front electrode part 602 and horizontally extending with respect to the support substrate 100. In this case, the third front electrode part 603 may directly make contact with the opposite side and the top surface of the second back electrode 220. Accordingly, the second solar cell C2 may be electrically to the first solar cell C1.

The third front electrode part 603 may horizontally extend with respect to the support substrate 100 so as to be connected to a back electrode spaced apart from the third front electrode part 603 by a first pattern P1. In this case, the third front electrode part 603 may directly make contact with the support substrate 100. In this case, since the third front electrode part 603 includes a transparent conductive material, even it is formed on the top surface of the support substrate 100 not to influence the transmittance of the solar cell.

FIGS. 3 to 5 are sectional views showing a method of fabricating the solar cell module according to the embodiment. The description about the solar cell and the solar cell module will be incorporated herein by reference.

Referring to FIG. 3, back electrode layers 200 are formed on the support substrate 100. The back electrode layers 200 may be fabricated by forming a back electrode on the support substrate 100 and forming a first pattern P1 separating the back electrode.

The first pattern P1 may be formed through a photo-lithography process. The back electrode layers 200 are spaced apart from each other through the first pattern P1. That is, the back electrode layers 200 are divided into a plurality of back electrodes through the first pattern P1. For example, the width of the first pattern P1 may be in the range of about 3 mm to about 7 mm. However, the embodiment is not limited to the above.

As described above, the solar cell module according to the embodiment may easily control an amount of light transmitting into the interior of the building by adjusting the first pattern P1. That is, the solar cell module according to the embodiment may control transmittance of the solar cell module by adjusting the first pattern P1.

Referring to FIG. 4, the light absorbing layer 300, the buffer layer 400, and the high resistance buffer layer 500 are sequentially formed on the back electrode layer 200.

The light absorbing layer 300 may be formed by a sputtering process or evaporation.

In detail, in order to form the light absorbing layer 300, a CIG based-metal precursor layer is formed on the back electrode layer 200 using a copper target, an indium target, and a gallium target. Next, the metal precursor layer reacts with selenium through a selenization process so that a CIGS based-light absorbing layer 300 is formed.

The buffer layer 400 may be formed by depositing cadmium sulfide on the light absorbing layer 300 through chemical bath deposition (CBD). Zinc oxide is deposited on the buffer layer 400 through sputtering and the high resistance buffer layer 500 is formed.

After that, referring to FIG. 4, a second pattern P2 is formed on the light absorbing layer 300, the buffer layer 400, and the high resistance butter layer 500.

Referring to FIG. 4, a process of forming the second pattern P1 is performed to space one side of the light absorbing layer 300 apart from one side of the back electrode layer 200 by a predetermined interval W1. For example, the predetermined interval W1 may be in the range of about 5 μm to about 20 μm. However, the embodiment is not limited to the above. If the interval W1 between the one side 301 of the light absorbing layer 300 and the one side 201 of the back electrode layer 200 is less than about 5 μm, the back electrode layer 200 is electrically connected to a front electrode layer 60 provided on the light absorbing layer 300 so that shunt may occur. If the interval W1 between the one side 301 of the light absorbing layer 300 and the one side 201 of the back electrode layer 200 is greater than about 20 μm, a contact area of the light absorbing part 310 provided on the support substrate 100 becomes wide so that transmittance of the solar cell module may be deteriorated.

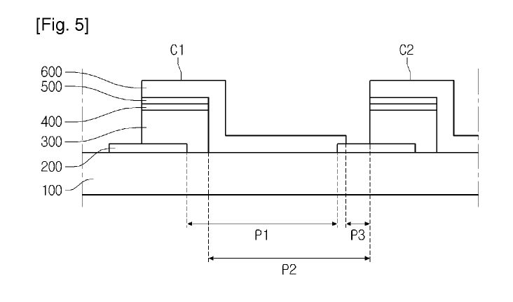

Referring to FIG. 5, a front electrode layer 600 is formed by laminating a transparent conductive material on the high resistance buffer layer 500. The front electrode layer 600 may be fabricated by forming a front electrode on the light absorbing layer 300 and forming a third pattern P3 separating the front electrode. The third pattern P3 may be formed by a mechanical method, and a part of the back electrode layer 300 is exposed. For example, the width of the third pattern P3 may be in the range of about 80 μm to about 200 μm, but the embodiment is not limited thereto.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode on a support substrate;
a light absorbing part on a top surface and one side of the back electrode; and
a front electrode on a top surface and one side of the light absorbing part and directly making contact with a top surface of the support substrate.

2. The solar cell of claim 1, wherein the front electrode comprises:
a first front electrode part on the top surface of the light absorbing part;
a second front electrode part connected to one end of the first front electrode part and provided on the one side of the light absorbing part; and
a third front electrode part connected to one end of the second front electrode part and horizontally extending with respect to the support substrate.

3. The solar cell of claim 2, wherein the third front electrode part directly makes contact with the top surface of the support substrate.

4. The solar cell of claim 2, wherein the first front electrode part the second front electrode part, and the third front electrode part are integrally formed with each other.

5. The solar cell of claim 1, wherein the one side of the light absorbing part corresponds to the one side of the back electrode, and
an interval between the one side of the light absorbing part and the one side of the back electrode is in a range of 5 μm to 20 μm.

6. The solar cell of claim 1, wherein the light absorbing part exposes a part of the back electrode.

7. The solar cell of claim 1, wherein the light absorbing part directly makes contact with the top surface of the support substrate.

8. A solar cell module comprising:
a first solar cell including a first back electrode on a support substrate, a first light absorbing part on a top surface and one side of the first back electrode, and a first front electrode on a top surface and one side of the first light absorbing part; and
a second solar cell including a second back electrode on the support substrate, a second light absorbing part on a top surface and one side of the second back electrode, and a second front electrode on a top surface and one side of the second light absorbing part.

9. The solar cell module of claim 8, wherein the first front electrode and the second front electrode directly make contact with a top surface of the support substrate, respectively.

10. The solar cell module of claim 8, wherein the first front electrode is electrically connected to the second back electrode.

11. The solar cell module of claim 10, wherein the first front electrode is provided on an opposite side and the top surface of the back electrode.

12. The solar cell module of claim 10, wherein the first front electrode comprises:
a first front electrode part on the top surface of the first light absorbing part;
a second front electrode part connected to one end of the first front electrode part and provided on the one side of the first light absorbing part; and
a third front electrode part connected to one end of the second front electrode part and horizontally extending with respect to the support substrate,
wherein the third front electrode part is electrically connected to the second back electrode.

13. The solar cell module of claim 8, wherein the second back electrode is spaced apart from the first back electrode, and
the second front electrode is spaced apart from the first front electrode.

14. The solar cell module of claim 13, wherein an interval between the first back electrode and the second back electrode is in a range of 3 mm to 7 mm.

15. The solar cell module of claim 8, wherein the solar cell module is a Building Integrated Photovoltaic (BIPV).

16-20. (canceled)

21. The solar cell module of claim 13, wherein an interval between the first back electrode and the second back electrode is in a range of 4 mm to 5 mm.
